(19) United States
(12) Patent Application Publication
(10) Pub. No.: US 2011/0012251 A1
(43) Pub. Date: Jan. 20, 2011

(54) SEMICONDUCTOR DEVICE AND METHOD FOR MANUFACTURING SAME

(75) Inventor: Satoshi TERAMAE, Hyogo-ken (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/833,728

(22) Filed: Jul. 9, 2010

(30) Foreign Application Priority Data
Jul. 14, 2009 (JP) 2009-165619

(51) Int. Cl. H01L 23/04; H01L 21/56

(52) U.S. Cl. 257/693; 438/127; 257/E23.181; 257/E21.502

(57) ABSTRACT

According to one embodiment, a semiconductor device includes a base substrate, at least one semiconductor chip provided above the base substrate, and a resin case covering the semiconductor chip and supported by the base substrate. A partition plate holds back extension of a crack occurring in the resin case being provided in the resin case.

### CROSS-REFERENCE TO RELATED APPLICATIONS

This application is based upon and claims the benefit of priority from the prior Japanese Patent Application No. 2009-165619, filed on Jul. 14, 2009; the entire contents of which are incorporated herein by reference.

### FIELD

Embodiments described herein relate generally to a semiconductor device and a method for manufacturing the same.

### BACKGROUND

A semiconductor device (power module) in which a power semiconductor element is mounted is used in inverter devices, uninterruptible power supply systems, machine tools, industrial robots, and the like.

Generally, such a semiconductor device has a configuration in which electric components including a semiconductor chip are sealed with a resin case. A device has been recently disclosed having a configuration in which an external connection terminal and a control terminal are pulled out from the interior of the resin case to the exterior of the resin case to meet the requirement of the downsizing of the semiconductor device and the like. Power is supplied to the semiconductor chip sealed with the resin case normally via the external connection terminal or the like fixed to the resin case.

However, when such a semiconductor device is driven, for example, a stress is applied to the resin case by a temperature cycle due to a difference in coefficient of thermal expansion between the resin case and the external connection terminal. Alternatively, a stress may be applied to the resin case by the direct application of a mechanical load from the outside of the semiconductor device to the external connection terminal. Such a stress may cause a crack in the resin case.

When the semiconductor device is used for a long period of time, the crack does not stay in the resin case but appears up to the surface of the resin case. This may cause a reduced mechanical strength and/or a poor external appearance of the semiconductor device.

### BRIEF DESCRIPTION OF THE DRAWINGS

FIGS. 1A and 1B are schematic views of a principal part of a semiconductor device according to a first embodiment;

FIG. 2 is a schematic view of a principal part of a semiconductor device according to the first embodiment;

FIG. 3A to FIG. 4C are views of a principal part for describing a manufacturing process of the semiconductor device according to the first embodiment;

FIGS. 5A and 5B are views describing the operation and effects of the semiconductor device according to the first embodiment;

FIGS. 6A and 6B and FIG. 7 are schematic views of a principal part of a semiconductor device according to a second embodiment;

FIGS. 8A and 8B are views of a principal part for describing the manufacturing process of the semiconductor device according to a third embodiment;

FIGS. 9A and 9B and FIG. 10 are schematic views of a principal part of a semiconductor device according to the third embodiment; and

FIG. 11 is a schematic cross-sectional view of a principal part of a semiconductor device according to a fourth embodiment.

### DETAILED DESCRIPTION

Embodiments will now be described with reference to the drawings.

In general, according to one embodiment, a semiconductor device includes a base substrate, at least one semiconductor chip provided above the base substrate, and a resin case covering the semiconductor chip and supported by the base substrate. A partition plate holds back extension of a crack occurring in the resin case being provided in the resin case.

According to another embodiment, a method for manufacturing a semiconductor device is disclosed. The method includes electrically connecting an electrode of at least one semiconductor chip provided above a base substrate to an external connection terminal supported by a molded body, and an outer frame member of a resin case is fixed to an upper end edge of the base substrate. A space surrounded by the base substrate and the outer frame member is filled with a resin and the semiconductor chip is covered with the resin. A first paste-like resin is injected into a first portion surrounded by the outer frame member, the resin, and a molded body provided with a partition plate and a second paste-like resin is injected into a second portion surrounded by the resin and the molded body provided with the partition plate. In addition, the first paste-like resin and the second paste-like resin are cured to form the resin case covering the semiconductor chip and including the molded body, the outer frame member, and a resin member on the base substrate.

According to another embodiment, a method for manufacturing a semiconductor device is disclosed. The method includes electrically connecting an electrode of at least one semiconductor chip provided above a base substrate to an external connection terminal supported by a molded body and an outer frame member of a resin case is fixed to an upper end edge of the base substrate. A space surrounded by the base substrate and the outer frame member is filled with a resin and the semiconductor chip is covered with the resin. A paste-like resin is poured through a first portion surrounded by the outer frame member, the resin, and a molded body provided with fragment-shaped partition plates or a second portion surrounded by the resin and the molded body provided with the partition plates and the paste-like resin is allowed to pass between the partition plates and the paste-like resin is injected into the first portion and the second portion. In addition, the paste-like resin is cured to form the resin case covering the semiconductor chip and including the molded body, the outer frame member, and a resin member on the base substrate.

### First Embodiment

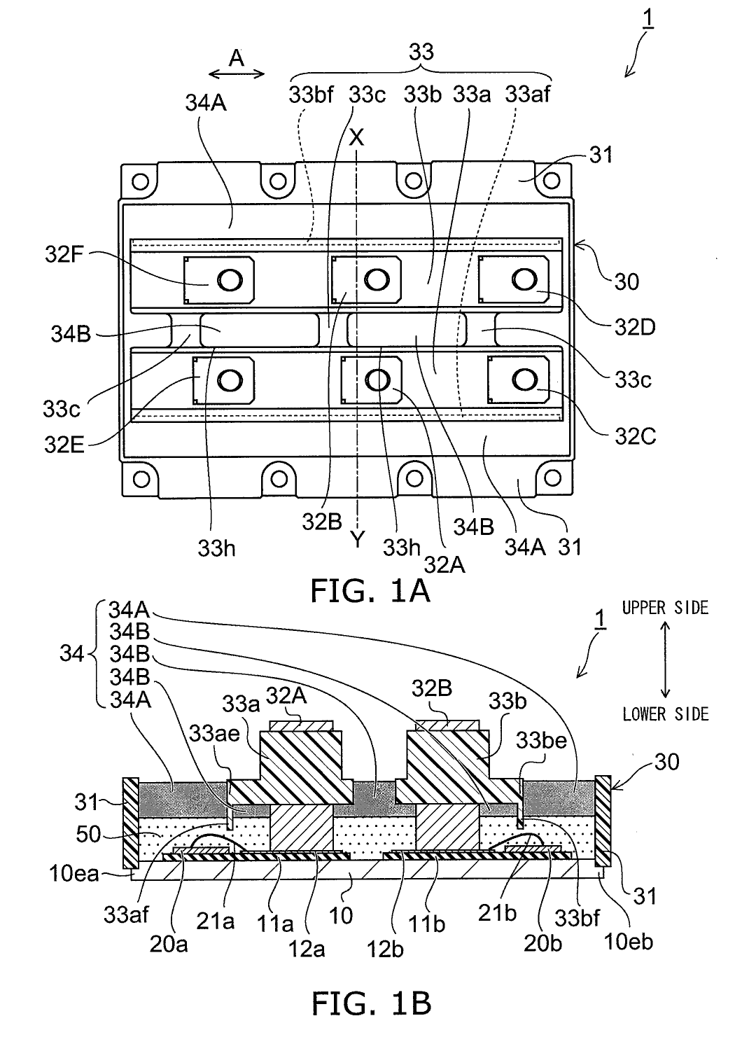

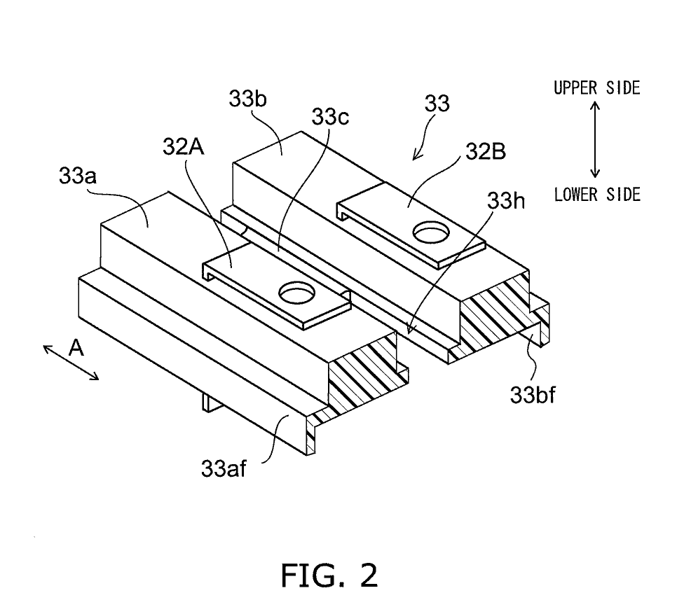

FIGS. 1A and 1B and FIG. 2 are schematic views of a principal part of a semiconductor device according to a first embodiment. FIG. 1A illustrates a plan view of the principal part of a semiconductor device 1, and FIG. 1B illustrates the X-Y cross section of FIG. 1A. FIG. 2 illustrates a perspective view of a central portion of a resin case 30 of the semiconductor device 1.

The semiconductor device 1 includes mainly a base substrate 10, semiconductor chips 20a and 20b provided above the base substrate 10, and the resin case 30 covering the semiconductor chips 20a and 20b. The semiconductor device 1 is, for example, a power module in which an inverter circuit and the like are mounted.

The plate-like base substrate 10 is provided in the semiconductor device 1 as the base thereof. The base substrate 10 is mainly made of, for example, a metal such as copper (Cu) and aluminum (Al), or aluminum silicon carbide (AlSiC). Insulating substrates 11a and 11b mainly made of, for example, a ceramic such as alumina (Al₂O₃), aluminium nitride (AlN), and silicon nitride (Si₃N₄) are selectively disposed on the base substrate 10. The semiconductor chip 20a is provided on the insulating substrate 11a, and an interconnection pattern 12a is selectively disposed outside the chip mounting region. Similarly, the semiconductor chip 20b is provided on the insulating substrate 11b, and an interconnection pattern 12b is provided outside the chip mounting region.

The semiconductor chips 20a and 20b are, for example, vertical power semiconductor elements such as power MOSFET (metal oxide semiconductor field effect transistor), IGBT (insulated gate bipolar transistor), and FWD (free wheeling diode). One ends of bonding wires 21a and 21b are connected to the upper-face electrodes (not illustrated) of the semiconductor chips 20a and 20b, respectively, and the other ends of the bonding wires 21a and 21b are connected to the interconnection patterns 12a and 12b, respectively.

In the semiconductor device 1, a resin case 30 is mounted on the base substrate 10 so as to cover the semiconductor chips 20a and 20b. The resin case 30 is a package member configured by combining several molded bodies and external connection terminals. For example, the resin case 30 is configured to include an outer frame member 31, a molded body 33, and a resin member 34 formed in portions other than the outer frame member 31 and the molded body 33.

Specifically, upper end edges 10ea and 10eb of the base substrate 10 support the outer frame member 31 which is a peripheral portion of the resin case 30. One end of an external connection terminal 32A is joined to the interconnection pattern 12a on the insulating substrate 11a. Similarly, one end of an external connection terminal 32B is joined to the interconnection pattern 12b on the insulating substrate 11b. These joinings are performed by, for example, soldering, laser welding, or the like.

Parts of the external connection terminals 32A and 32B are sealed with molded members 33a and 33b, respectively, in the resin case 30. The molded member 33a (first molded member) and the molded member 33b (second molded member) are made of a resin, and are connected by a resin bar 33c provided between the molded member 33a and the molded member 33b. In this embodiment, a partition member (partition plate) 33af extends from an outer end 33ae of the molded member 33a toward the underside (the base substrate 10 side) of the semiconductor device 1. Similarly, a partition member 33bf extends from an outer end 33be of the molded member 33b toward the underside of the semiconductor device 1. The partition members 33af and 33bf are configured to continue in the direction indicated by the arrow “A” in the drawing (the direction in which the molded member 33a and the molded member 33b extend).

That is, the molded body 33 in which the molded member 33a, the molded member 33b, the resin bar 33c connecting the molded member 33a and the molded member 33b, and the partition member 33af (first partition member) and the partition member 33bf (second partition member) continuing in the direction of the arrow “A” are formed as one body is disposed in the central portion of the resin case 30. FIG. 2 illustrates a perspective view of the molded body 33.

As described above, the molded body 33 extends the partition members 33af and 33bf from the outer ends 33ae and 33be of the molded members 33a and 33b, respectively. The region surrounded by the resin bars 33c adjacent to the molded members 33a and 33b forms a hole 33h.

In the semiconductor device 1, a resin member 34A for connecting the outer frame member 31 and the molded body 33 is provided between the outer frame member 31 and the molded body 33 (see FIG. 1B). A resin member 34B is provided in the hole 33h of the molded body 33. The resin member 34B goes round and cut in to the lower face side of the molded body 33. The partition members 33af and 33bf are configured to continue in the direction of the arrow “A” as viewed from a direction substantially perpendicular to the face at which the partition members 33af and 33bf are in contact with the resin members 34A and 34B.

Thus, the resin case 30 is a package member in which the outer frame member 31, the molded body 33, and the resin member 34 are formed as one body. In particular, the lower portion of the molded body 33 has a configuration in which the partition members 33af and 33bf extend in the resin member 34 to partition the resin member 34 into the resin member 34A and the resin member 34B.

The outer frame member 31 is made of, for example, a PPS (polyphenylene sulfide) resin. The molded body 33 is made of, for example, a PBT (polybutylene terephthalate) resin. Inorganic glass fillers mainly made of silicon oxide (SiO₂) and the like are dispersed in the molded body 33. Inorganic glass fillers may be dispersed also in the outer frame member 31. The resin members 34A and 34B are made of, for example, a thermosetting epoxy resin.

In addition to the external connection terminals 32A and 32B, external connection terminals 32C to 32F are provided in the semiconductor device 1. At least one of the external connection terminals 32A to 32F is connected either to a main electrode (source, drain) of the semiconductor chips 20a and 20b or to the control electrode (gate). The external connection terminals 32A to 32F are made of, for example, copper (Cu). The surfaces of the external connection terminals 32A to 32F may be plated with nickel (Ni) or Au (gold)/Ni.

In the semiconductor device 1, the space surrounded by the base substrate 10 and the resin case 30 is filled with a gel (gel resin) 50 in order to protect the semiconductor chips 20a and 20b, the bonding wires 21a and 21b, and the like.

When the semiconductor device 1 thus configured is used, the external connection terminals 32A to 32F are screwed to interconnection bus bars outside the semiconductor device 1, while the base substrate 10 is in contact with an external cooling system (cooling fin, water-cooling apparatus, etc.) outside the semiconductor device 1.

A method for fabricating the semiconductor device 1 will now be described.

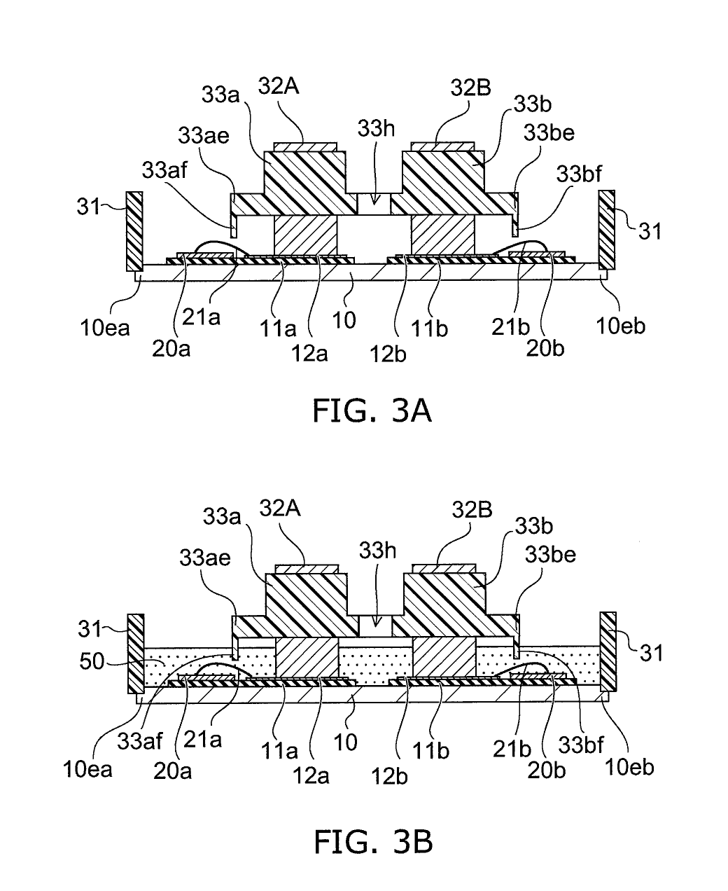

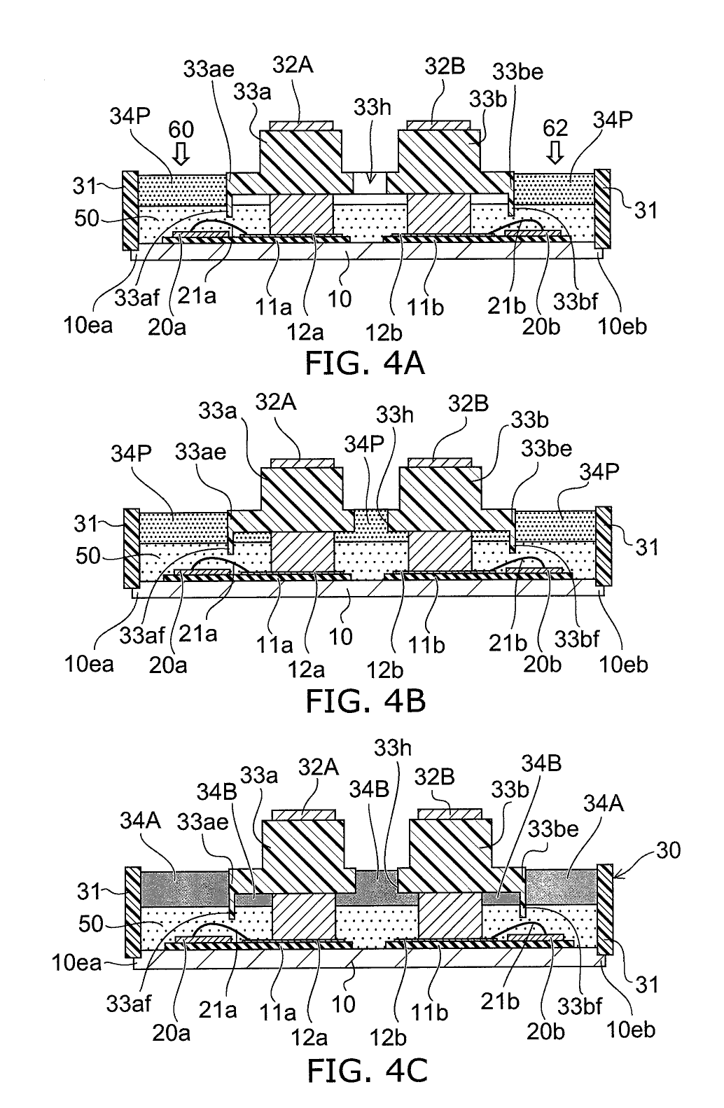

FIG. 3A to FIG. 4C are views of a principal part for describing the manufacturing process of the semiconductor device according to the first embodiment. These fabrication drawings illustrate a cross section along the X-Y of FIG. 1A.

First, as illustrated in FIG. 3A, the outer frame member 31 which is a peripheral portion of the resin case 30 is fixed to the upper end edges 10ea and 10eb of the base substrate 10, and one ends of the external connection terminals 32A and 32B are joined onto the interconnection patterns 12a and 12b, respectively. The outer frame member 31 is a previously processed molded body. Parts of the external connection terminals 32A and 32B are sealed with the molded body 33 as described above.

At this stage, the insulating substrates 11a and 11b have been already provided on the base substrate 10, and the semiconductor chips 20a and 20b have been already provided on the insulating substrates 11a and 11b, respectively. Furthermore, the bonding wires 21a and 21b have been provided by wire bonding.

Next, as illustrated in FIG. 3B, the gel 50 is provided in order to protect the semiconductor chips 20a and 20b, the bonding wires 21a and 21b, and the like. For example, the gel 50 is provided so that the lower ends of the partition members 33af and 33bf may be located slightly below the surface of the gel 50. Thereby, the semiconductor chips 20a and 20b, the bonding wires 21a and 21b, and the like are covered with the gel 50.

Next, as illustrated in FIG. 4A, a paste-like thermosetting resin 34p is injected into the portions surrounded by the molded body 33, the gel 50, and the outer frame member 31 (first portions (first spaces) indicated by the arrows 60 and 62 of FIG. 4A) by transfer molding.

Subsequently, as illustrated in FIG. 4B, the paste-like thermosetting resin 34p is poured through the hole 33h of the molded body 33 to be injected into a second portion (second space) surrounded by the molded body 33 and the gel 50. Then, the thermosetting resin 34p on the gel 50 is heated to be cured. Thereby, as illustrated in FIG. 4C, the resin member 34A is formed in the first portions surrounded by the molded body 33, the gel 50, and the outer frame member 31, and the resin member 34B is formed in the hole 33h and on the lower face side of the molded body 33.

The above process forms the resin case 30 illustrated in FIG. 1, leading to the formation of the semiconductor device 1.

The procedure of injecting the thermosetting resin 34p is not limited to the order described above, but any order is possible. Alternatively, the thermosetting resin 34p injected from the arrows 60 and 62 and the thermosetting resin 34p injected through the hole 33h may be injected simultaneously. The resin members 34A and 34B and the adherend bodies thereof (the outer frame member 31 and the molded body 33) are bonded by hydrogen bonds due to ring-opening of epoxy groups contained in the resin members 34A and 34B.

The operation and effects of the semiconductor device 1 will now be described.

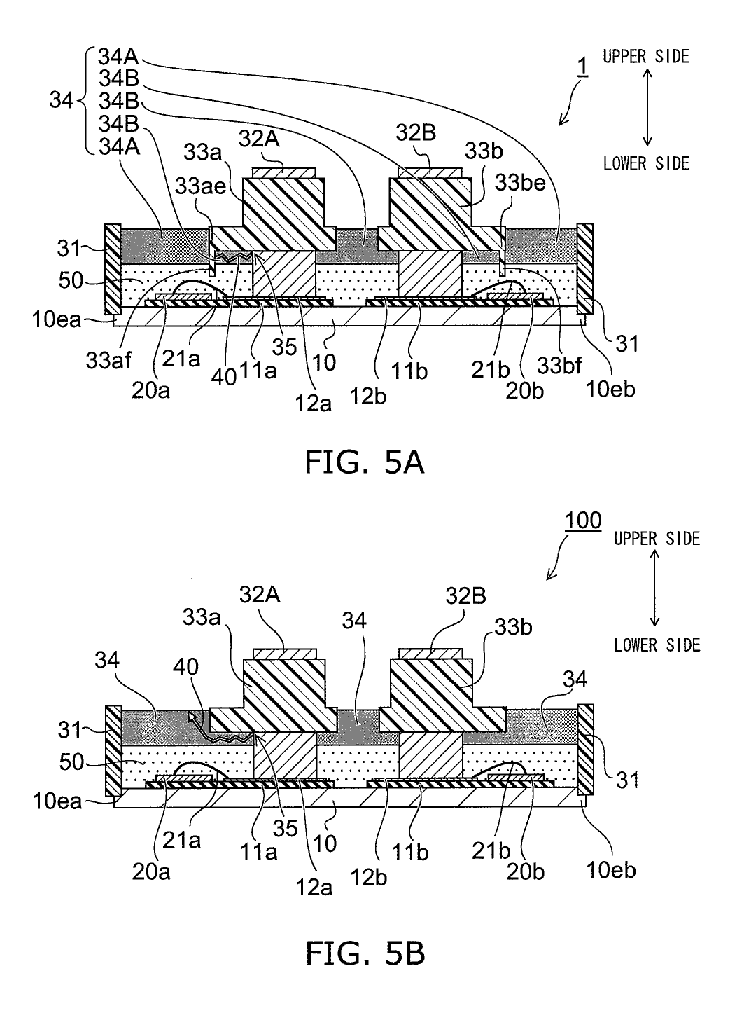

FIGS. 5A and 5B are views describing the operation and effects of the semiconductor device according to the first embodiment. FIG. 5A illustrates the semiconductor device 1 which is this embodiment, and FIG. 5B illustrates a semiconductor device 100 according to a comparative example.

When the semiconductor device 1 illustrated in FIG. 5A is operated, a current is applied to the semiconductor chips 20a and 20b which are power semiconductor elements, and heat is released from the semiconductor chips 20a and 20b. This heat is transmitted also to the upper portion of the semiconductor device 1 to heat the resin case 30.

Here, there is a difference in coefficient of thermal expansion between the outer frame member 31 and the molded body 33, and the resin members 34A and 34B which are thermosetting resins. The external connection terminals 32A and 32B are fixed to external interconnection bus bars (not illustrated) by screwing or the like. Therefore, a direct stress is applied to the external connection terminal 32A and the external connection terminal 32B also from the outside of the semiconductor device 1. Consequently, if ON and OFF of the semiconductor chips 20a and 20b are repeated, the thermal cycle thereof causes intermittent stresses applied to the interface between the outer frame member 31 and the resin member 34A, the interfaces between the molded body 33, and the resin members 34A and 34B, and the interfaces between the external connection terminals 32A and 32B, and the resin member 34B.

If the semiconductor device 1 is used for a long period of time in such a situation, a crack 40 may occur at a certain place in the resin case 30. For example, since the outer frame member 31 and the molded body 33 of this embodiment are made of a strong material as compared with the resin members 34A and 34B, the crack 40 occurs less readily in the outer frame member 31 and the molded body 33. Therefore, the crack 40 starts to occur from the interfaces between the resin members 34A and 34B, and the adherend bodies.

In particular, since a direct stress is applied to the external connection terminal 32A and the external connection terminal 32B also from the outside of the semiconductor device 1, the crack 40 occurs readily at the interfaces 35 between the external connection terminals 32A and 32B, and the resin member 34B.

In FIG. 5A, an example is illustrated in which the crack 40 occurs from the interface 35 between the external connection terminal 32A and the resin member 34B and extends to a certain length. The crack 40 of the sort has the property of growing and continuing to extend in accordance with the operating time of the semiconductor device 1.

However, in the semiconductor device 1, the partition member 33af is provided at the outer end 33ae of the molded member 33a. The extension of the crack 40 is held back due to the presence of the partition member 33af. Therefore, even if the semiconductor device 1 is used for a long period of time, the crack 40 is held back in the resin member 34B, and the mechanical strength and external appearance of the resin case 30 are retained.

In contrast, in the semiconductor device 100 illustrated in FIG. 5B, the partition members 33af and 33bf described above are not provided. That is, the resin member 34 of the semiconductor device 100 is not partitioned below the molded members 33a and 33b, but forms a single-body resin layer in the resin case 30.

In the semiconductor device 100 thus configured, the crack 40 continues to extend in the resin member 34 in accordance with the operating time of the semiconductor device 100. For example, if the crack 40 continues to extend not in a longitudinal direction of the molded body 33 (the arrow “A”) but in a direction nonparallel to the “A” direction, the crack 40 continues to grow in the single-body resin member 34 to finally reach the surface of the resin case 30. Such a state significantly reduces the mechanical strength of the semiconductor device. Furthermore, if the crack 40 reaches the surface of the resin case 30, moisture in the atmosphere may come into the semiconductor device 100 through the crack 40. Therefore, the moisture resistance of the semiconductor device 100 degrades. Furthermore, the crack 40 is seen from the outside of the semiconductor device 100, resulting in a poor external appearance of the semiconductor device.

In particular, if the crack 40 reaches the surface of the resin case 30, the molded body 33 is no longer sufficiently fixed and supported by the resin member 34. In other words, the molded member 33a which has supported the external connection terminal 32A becomes almost free of the resin case 30. In such a state, the stress from the outside of the semiconductor device 100 is directly applied to the external connection terminal 32A. If such a stress concentrates at the joint portion between the external connection terminal 32A and the interconnection pattern 12a, a crack occurs in this joint portion and/or this joint portion is peeled off.

However, the resin case 30 of the semiconductor device 1 maintains the state in which the outer frame member 31, the molded body 33, and the resin members 34A and 34B form one body, even if the resin case 30 is used for a long period of time. This prevents the stress from the outside of the semiconductor device 1 from being applied intensively to the external connection terminal 32A. Consequently, the crack and peeling-off of the joint portion described above occur less readily.

Thus, the semiconductor device 1 maintains a high mechanical strength and a high moisture resistance, and has high reliability. Furthermore, it is free from a poor external appearance.

FIG. 1B illustrates a configuration in which the lower ends of the partition members 33af and 33bf are protruded downward from the lower face of the resin member 34. This embodiment includes also a configuration in which the lower ends of the partition members 33af and 33bf are located above the lower face of the resin member 34. In this case, the lower ends of the partition members 33af and 33bf are sealed with the resin member 34, and the lower ends of the partition members 33af and 33bf are located lower than the crack 40. Even in such a configuration, since the lower ends of the partition members 33af and 33bf are lower than the location of the crack 40, the extension of the crack 40 is suppressed.

Examples will now be described in which the configuration of the semiconductor device 1 is modified. In the drawings illustrated below, members identical to the semiconductor device 1 are marked with the same reference numerals and a detailed description thereof is omitted as appropriate.

### Second Embodiment

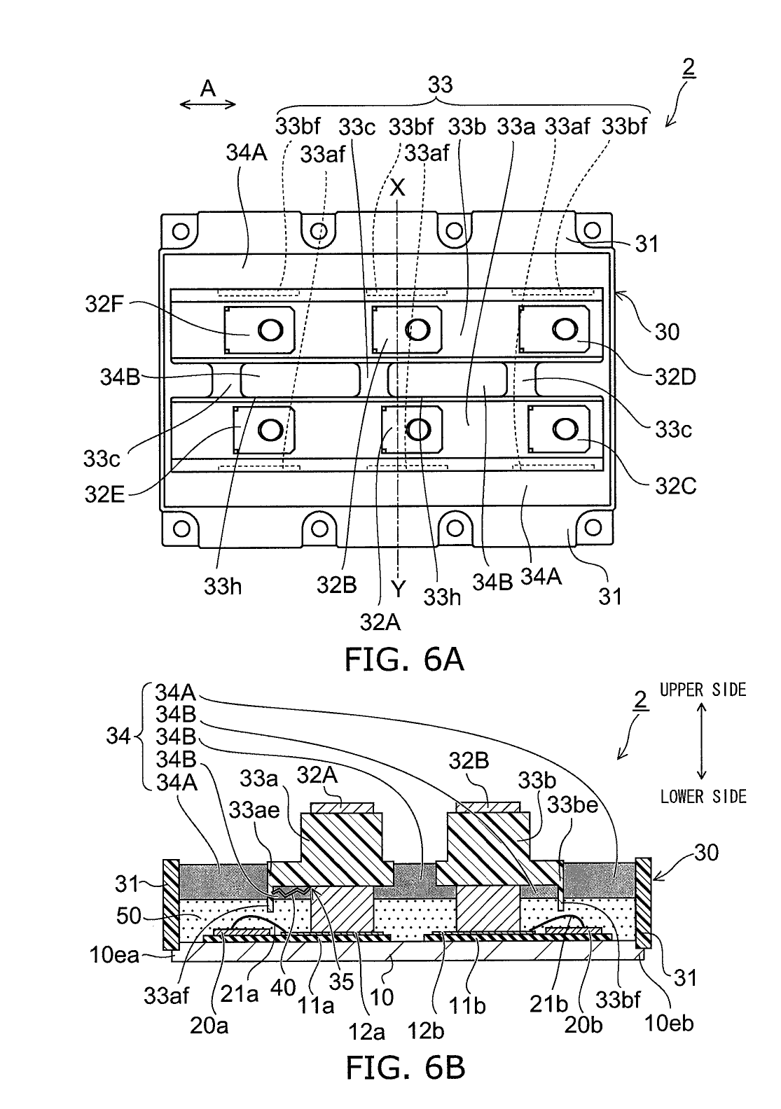

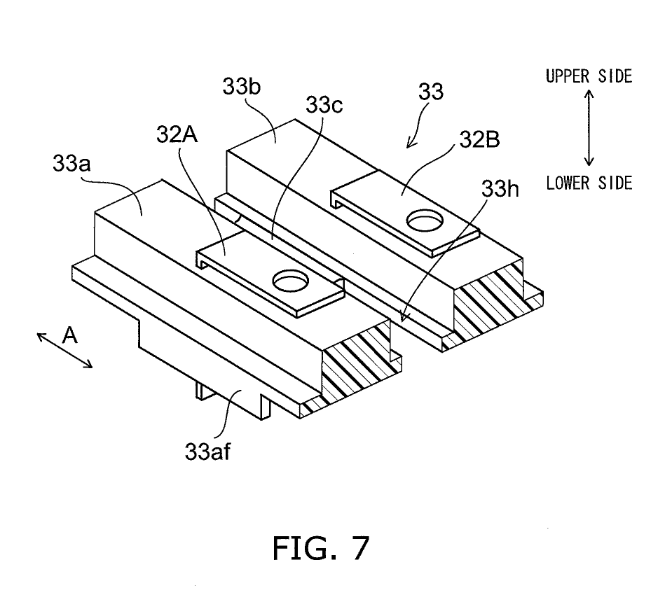

FIGS. 6A and 6B and FIG. 7 are schematic views of a principal part of a semiconductor device according to a second embodiment. FIG. 6A illustrates a plan view of the principal part of a semiconductor device 2, and FIG. 6B illustrates the X-Y cross section of FIG. 6A. FIG. 7 illustrates a perspective view of the molded body 33 in a central portion of the resin case 30.

As illustrated in FIGS. 6A and 6B, the semiconductor device 2 is configured to include the base substrate 10, the semiconductor chips 20a and 20b provided above the base substrate 10, and the resin case 30 covering the semiconductor chips 20a and 20b. The resin case 30 is configured to include the outer frame member 31, the molded body 33, and the resin member 34 formed in portions other than the outer frame member 31 and the molded body 33.

Specifically, the upper end edges 10ea and 10eb of the base substrate 10 support the outer frame member 31 which is a peripheral portion of the resin case 30. One end of the external connection terminal 32A is joined to the interconnection pattern 12a on the insulating substrate 11a. Similarly, one end of the external connection terminal 32B is joined to the interconnection pattern 12b on the insulating substrate 11b.

Parts of the external connection terminals 32A and 32B are sealed with the molded members 33a and 33b in the resin case 30. The molded member 33a and the molded member 33b are connected by the resin bar 33c provided between the molded member 33a and the molded member 33b. The partition member 33af extends from the outer end 33ae of the molded member 33a toward the underside of the semiconductor device 2. Similarly, the partition member 33bf extends from the outer end 33be of the molded member 33b toward the underside of the semiconductor device 2.

However, as illustrated in FIG. 7, the partition members 33af and 33bf of the semiconductor device 2 are configured in fragment shapes. For example, the partition members 33af and 33bf having strip shapes are provided near the external connection terminals 32A and 32B. The partition members 33af and 33bf are provided not only near the external connection terminals 32A and 32B but also near the external connection terminals 32C to 32F (see FIG. 6A).

That is, the molded body 33 in which the molded member 33a, the molded member 33b, the resin bar 33c connecting the molded member 33a and the molded member 33b, and the fragment-shaped partition members 33af and 33bf are formed as one body is disposed in the central portion of the resin case 30.

The resin member 34A for connecting the outer frame member 31 and the molded body 33 is provided between the outer frame member 31 and the molded body 33. The resin member 34B is provided in the hole 33h between the resin bars 33c of the molded body 33. The resin member 34B goes round and cut in to the lower face side of the molded body 33. The partition members 33af and 33bf are shaped like fragments as viewed from a direction substantially perpendicular to the face at which the partition members 33af and 33bf are in contact with the resin members 34A and 34B. Accordingly, the resin member 34A and the resin member 34B are formed as one body through portions other than the partition members.

Thus, the resin case 30 is a package member in which the outer frame member 31, the molded body 33, and the resin member 34 are formed as one body. The partition members 33af and 33bf are configured to extend in the resin member 34 to partition the resin member 34 into the resin member 34A and the resin member 34B.

A method for fabricating the semiconductor device 2 will now be described. In this fabrication, since FIG. 3A and FIG. 3B described above can be used correspondingly, a description is given from the process of forming the resin members 34A and 34B.

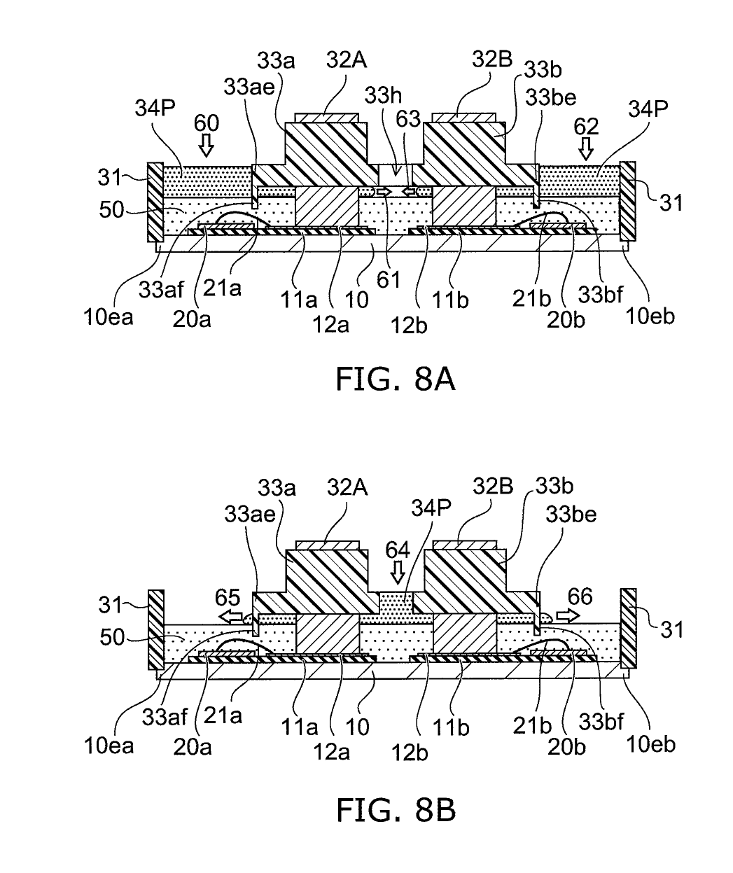

FIGS. 8A and 8B are views of a principal part for describing the manufacturing process of the semiconductor device according to the second embodiment.

In the formation process of the semiconductor device 2, the partition members 33af and 33bf are shaped like fragments, and therefore the paste-like thermosetting resin 34p can pass between the partition members 33af and between the partition members 33bf.

For example, as illustrated in FIG. 8A, the paste-like thermosetting resin 34p is poured from the arrows 60 and 62 to be injected into the portions surrounded by the molded body 33, the gel 50, and the outer frame member 31. This thermosetting resin 34p passes between the partition members 33af and between the partition members 33bf (the arrows 61 and 63) to be finally injected into the portion surrounded by the molded body 33 and the gel 50.

Alternatively, as illustrated in FIG. 8B, the thermosetting resin 34p is poured through the hole 33h of the molded body 33 (the arrow 64) to be injected into the portion surrounded by the molded body 33 and the gel 50. This thermosetting resin 34p passes between the partition members 33af and between the partition members 33bf (the arrows 65 and 66) to be finally injected into the portions surrounded by the molded body 33, the gel 50, and the outer frame member 31.

Therefore, only a single injection of the thermosetting resin 34p is needed for forming the resin member 34 of the semiconductor device 2. After that, the thermosetting resin 34p on the gel 50 is heated to be cured. Thereby, the resin case 30 illustrated in FIGS. 6A and 6B is formed, leading to the formation of the semiconductor device 2.

Thus, in the semiconductor device 2, the partition members 33af and 33bf are provided at the outer ends 33ae and 33be of the molded members 33a and 33b. The extension of the crack 40 is held back due to the presence of the partition members 33af and 33bf. Therefore, even if the semiconductor device 2 is used for a long period of time, the crack 40 is held back in the resin member 34B, and the mechanical strength and external appearance of the resin case 30 are retained. Consequently, the semiconductor device 2 maintains a high mechanical strength and a high moisture resistance and has high reliability similarly to the semiconductor device 1. Furthermore, it is free from a poor external appearance.

In the semiconductor device 2, the resin member 34A and the resin member 34B can be formed by a single injection of the thermosetting resin 34p. Consequently, the manufacturing process can be shortened, and this improves the productivity of the semiconductor device 2.

### Third Embodiment

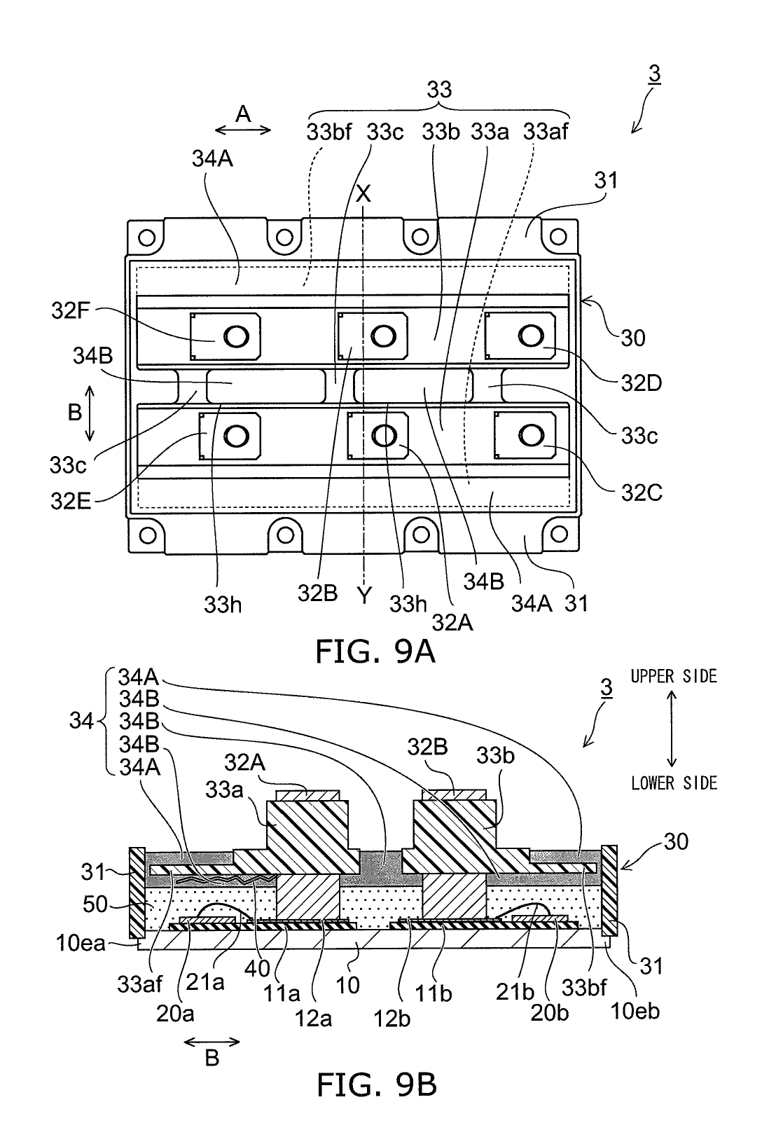

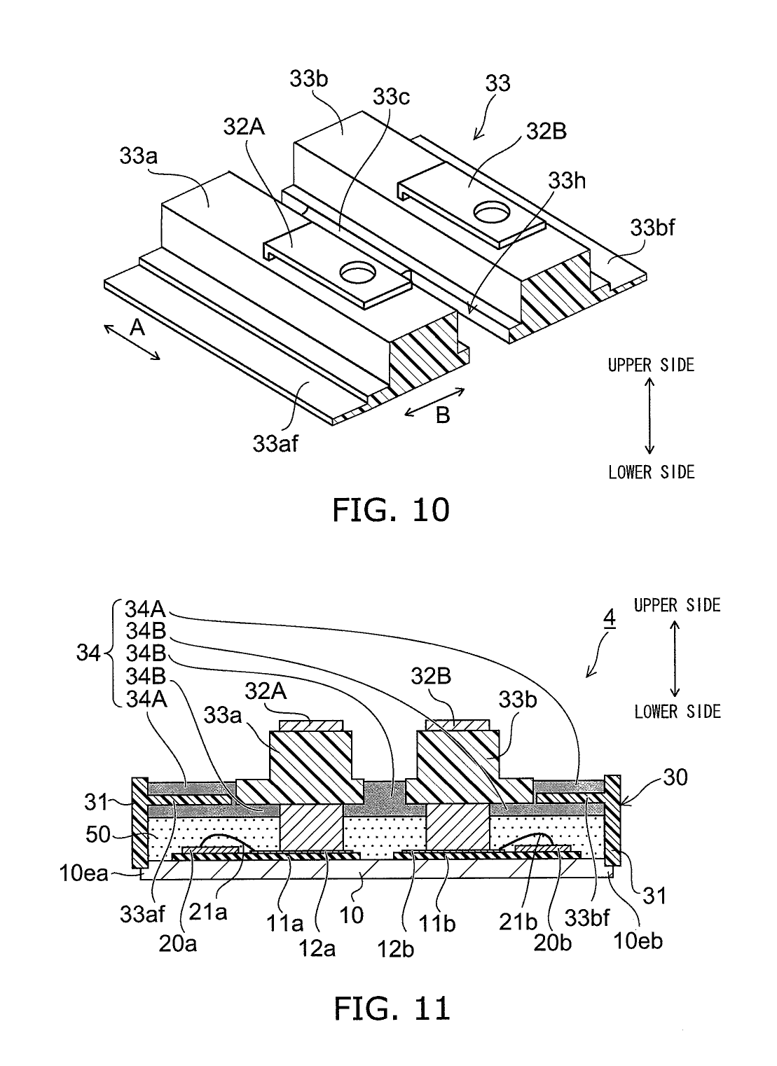

FIGS. 9A and 9B and FIG. 10 are schematic views of a principal part of a semiconductor device according to a third embodiment. FIG. 9A illustrates a plan view of the principal part of a semiconductor device 3, and FIG. 9B illustrates the X-Y cross section of FIG. 9A. FIG. 10 illustrates a perspective view of the molded body 33 in a central portion of the resin case 30.

As illustrated in FIGS. 9A and 9B, the semiconductor device 3 is configured to include the base substrate 10, the semiconductor chips 20a and 20b provided above the base substrate 10, and the resin case 30 covering the semiconductor chips 20a and 20b. The resin case 30 is configured to include the outer frame member 31, the molded body 33, and the resin member 34 formed in portions other than the outer frame member 31 and the molded body 33.

For example, the upper end edges 10ea and 10eb of the base substrate 10 support the outer frame member 31 which is a peripheral portion of the resin case 30. One end of the external connection terminal 32A is joined to the interconnection pattern 12a on the insulating substrate 11a. Similarly, one end of the external connection terminal 32B is joined to the interconnection pattern 12b on the insulating substrate 11b.

Parts of the external connection terminals 32A and 32B are sealed with the molded members 33a and 33b in the resin case 30. The molded member 33a and the molded member 33b are connected by the resin bar 33c provided between the molded member 33a and the molded member 33b. The partition member 33af extends from the outer end 33ae of the molded member 33a toward the outer frame member 31 near the outer end 33ae. Similarly, the partition member 33bf extends from the outer end 33be of the molded member 33b toward the outer frame member 31 near the outer end 33be.

That is, the molded body 33 in which the molded member 33a, the molded member 33b, the resin bar 33c connecting the molded member 33a and the molded member 33b, and the partition members 33af and 33bf extended from the molded members 33a and 33b in the direction of the arrow “B” are formed as one body is disposed in the central portion of the resin case 30. The partition members 33af and 33bf are configured to continue in the direction of the arrow “A”.

The resin member 34A for connecting the outer frame member 31 and the molded body 33 is provided between the outer frame member 31 and the molded body 33. The resin member 34B is provided in the hole 33h between the resin bars 33c of the molded body 33. The resin member 34B goes round and cut in to the lower face side of the molded body 33.

Thus, the resin case 30 is a package member in which the outer frame member 31, the molded body 33, and the resin member 34 are formed as one body. The partition members 33af and 33bf are configured to extend in the resin member 34 to partition the resin member 34 into the resin member 34A and the resin member 34B.

Also in the semiconductor device 3, the extension of the crack 40 is held back due to the presence of the partition members 33af and 33bf extending in the horizontal direction of the semiconductor device 3. Therefore, even if the semiconductor device 3 is used for a long period of time, the crack 40 is held back in the resin member 34B, and the mechanical strength and external appearance of the resin case 30 are retained. Consequently, the semiconductor device 3 maintains a high mechanical strength and a high moisture resistance and has high reliability similarly to the semiconductor device 1. Furthermore, it is free from a poor external appearance.

FIGS. 9A and 9B and FIG. 10 illustrate the configuration of the partition members 33af and 33bf continuing in the arrow “A” direction. This embodiment includes also a configuration in which the partition members 33af and 33bf having strip shapes are provided near the external connection terminals 32A to 32F as in the case of the semiconductor device 2. Even such a configuration sufficiently suppresses the growth of the crack 40 due to the presence of the partition members 33af and 33bf.

### Fourth Embodiment

FIG. 11 is a schematic cross-sectional view of a principal part of a semiconductor device according to a fourth embodiment.

In a semiconductor device 4, the partition members 33af and 33bf described above are provided on the outer frame member 31 side. The partition members 33af and 33bf may be either continuous or in fragment shapes.

Even the semiconductor device 4 thus configured can separate the resin member 34A and the resin member 34B from each other with the partition members 33af and 33bf. Thereby, the growth of the crack 40 can be held back in the resin member 34B, and effects similar to the semiconductor devices described above can be obtained.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the invention.

1. A semiconductor device comprising:
a base substrate;
at least one semiconductor chip provided above the base substrate; and
a resin case covering the semiconductor chip and supported by the base substrate,
a partition plate holding back extension of a crack occurring in the resin case being provided in the resin case.

2. The device according to claim 1, wherein
the resin case includes:
a molded body sealing part of an external connection terminal electrically connected to an electrode of the semiconductor chip;
an outer frame member supported at an upper end edge of the base substrate; and
a resin member formed in a portion other than the molded body and the outer frame member and
the partition plate extends from at least one of the molded body and the outer frame member into the resin member.

3. The device according to claim 2, wherein the partition plate is continuous or in a fragment shape as viewed from a direction substantially perpendicular to a face at which the partition plate is in contact with the resin member.

4. The device according to claim 2, wherein the partition plate is provided near the external connection terminal.

5. The device according to claim 2, wherein the partition plate extends from an outer end of the molded body to a side of the base substrate.

6. The device according to claim 2, wherein the partition plate extends from an outer end of the molded body toward the outer frame member.

7. The device according to claim 2, wherein inorganic glass fillers are dispersed in the molded body.

8. The device according to claim 2, wherein inorganic glass fillers are dispersed in the outer frame member.

9. The device according to claim 2, wherein the molded body is made of a polybutylene terephthalate resin.

10. The device according to claim 2, wherein the outer frame member is made of a polyphenylene sulfide resin.

11. The device according to claim 2, wherein the resin member is made of an epoxy resin.

12. The device according to claim 2, wherein the molded body includes:
a first molded member;
a second molded member; and
a resin bar connecting the first molded member to the second molded member.

13. A method for manufacturing a semiconductor device comprising:
electrically connecting an electrode of at least one semiconductor chip provided above a base substrate to an external connection terminal supported by a molded body and fixing an outer frame member of a resin case to an upper end edge of the base substrate;
filling a space surrounded by the base substrate and the outer frame member with a resin to cover the semiconductor chip with the resin;
injecting a first paste-like resin into a first portion surrounded by the outer frame member, the resin, and a molded body provided with a partition plate and injecting a second paste-like resin into a second portion surrounded by the resin and the molded body provided with the partition plate; and
curing the first paste-like resin and the second paste-like resin to form the resin case covering the semiconductor chip and including the molded body, the outer frame member, and a resin member on the base substrate.

14. The method according to claim 13, wherein the first paste-like resin is injected from the first portions and simultaneously the second paste-like resin are injected from the second portion.

15. A method for manufacturing a semiconductor device comprising:
electrically connecting an electrode of at least one semiconductor chip provided above a base substrate to an external connection terminal supported by a molded body and fixing an outer frame member of a resin case to an upper end edge of the base substrate;
filling a space surrounded by the base substrate and the outer frame member with a resin to cover the semiconductor chip with the resin;
pouring a paste-like resin through a first portion surrounded by the outer frame member, the resin, and a molded body provided with fragment-shaped partition plates or a second portion surrounded by the resin and the molded body provided with the partition plates and allowing the paste-like resin to pass between the partition plates to inject the paste-like resin into the first portion and the second portion; and
curing the paste-like resin to form the resin case covering the semiconductor chip and including the molded body, the outer frame member, and a resin member on the base substrate.
